(19) United States
(12) Patent Application Publication
(10) Pub. No.: US 2017/0194040 A1
(43) Pub. Date: Jul. 6, 2017

(54) PROGRAM AND DEVICE FOR SUPPRESSING TEMPERATURE RISE OF MEMORY

(71) Applicant: FIXSTARS CORPORATION, Tokyo (JP)

(72) Inventors: Satoshi Yoneya, Tokyo (JP); Ryoji Tsuchiyama, Tokyo (JP); Masana Murase, Tokyo (JP); Noriyuki Futatsugi, Tokyo (JP)

(73) Assignee: FIXSTARS CORPORATION, Tokyo (JP)

(21) Appl. No.: 15/302,092

(22) PCT Filed: Nov. 11, 2014
(86) PCT No.: PCT/JP2014/079823

§ 371 Date: Mar. 13, 2017

(30) Foreign Application Priority Data
Apr. 7, 2014 (JP) 2014-078713

(51) Int. Cl. G11C 7/10; G11C 11/34

(52) U.S. Cl. CPC G11C 7/1045; G11C 11/34; G11C 11/413

(57) ABSTRACT

A memory having stacked memory modules in which heat generated during memory read/write operations can be effectively dissipated, thus avoiding an undesirable localized temperature rise. The storage device is provided with a plurality of stacked memory modules. When a data write request is received, a data processing device that fulfills the role of a memory controller sequentially selects a memory module that is to be a write destination in such a manner that memory modules to which data is written simultaneously are not adjacent to each other, and in a series of write sequences, the memory module to which data is to be written at a subsequent write timing is not adjacent to the memory module to which data is written at a preceding write timing. As a result, the locations of heat generation among the plurality of stacked memory modules are distributed, reducing a rise in temperature.

### TECHNICAL FIELD

The present invention pertains to a technique for suppressing a temperature rise in a memory in which heat is generated when data is written to and read from the memory.

### BACKGROUND ART

In many types of memory, such as a semiconductor memory, heat is generated when data is written to or read from the memory. If a memory temperature becomes excessively high, thermal runaway may occur, and in turn read/write failure may occur.

As disclosed in JP2010-009674A there is known in the art a technique for suppressing thermal runaway in a semiconductor memory. More specifically, there is disclosed in JP2010-009674A a semiconductor device provided with a static memory cell, wherein, when a temperature measured inside the semiconductor device reaches a threshold value, a voltage applied to memory modules within the semi-conductor device is reduced to prevent overheating.

A high degree of memory integration can be achieved by stacking memory modules. However, a drawback of this technique is that effective dissipation of heat generated during read/write operations to the memory modules is prevented due to the presence of adjacent memory modules, as a result of which an excessive localized temperature rise is liable to occur.

### SUMMARY

In view of the problem outlined above, it is an object of the present invention to provide a memory comprising stacked memory modules in which heat generated during memory read/write operations can be effectively dissipated, thus avoiding an undesirable localized temperature rise.

To solve the foregoing problem, as a first embodiment of the present invention there is proposed a device comprising: a request acquisition unit that acquires a data write request; a selection unit that selects write destination memory modules from among a plurality of stacked memory modules in accordance with the data write request, so that two or more memory modules to which data is written within a predetermined time frame are not adjacent to one another; and a write instruction unit that instructs writing of data to the memory modules selected by the selection unit in accordance with the data write request.

As a second embodiment of the present invention there is proposed a configuration in which, the selection unit selects the write destination memory modules from among the plurality of stacked memory modules so that two or more memory modules to which data is written simultaneously are not adjacent to one another.

As a third embodiment of the present invention there is proposed a configuration in which, in the first or second embodiment, if the selection unit selects, from among the plurality of stacked memory modules, a first memory module to which data is to be written at a first write timing, the selection unit selects a memory module that is not adjacent to the first memory module as a second memory module to which data is to be written at a second write timing, the second write timing being subsequent to the first write timing.

As a fourth embodiment of the present invention there is proposed a configuration in which, in any of the first three embodiments, a selection data acquisition unit that acquires selection data, which is a plurality of items of data that identify one or more memory modules selected from among the plurality of stacked memory modules, arranged chronologically, is provided, and the selection unit selects memory modules as write destinations according to the selection data.

As a fifth embodiment of the present invention there is proposed a configuration in which, in the fourth embodiment, an identification data acquisition unit that acquires identification data that identifies eligible memory modules from among the plurality of stacked memory modules and an identification data output unit that outputs the identification data are provided, and the selection data acquisition unit acquires the selection data that is input as a response to the output of the identification data.

As a sixth embodiment of the present invention there is proposed a configuration in which, in any of the first five embodiments, a temperature data acquisition unit that acquires temperature data indicating a temperature measured at a representative point of the plurality of stacked memory modules is provided, and the selection unit modifies a number of two or more memory modules to which data is to be written within a predetermined time in accordance with the temperature indicated by the temperature data.

As a seventh embodiment of the present invention there is proposed a configuration in which, in any one of the first six embodiments, the plurality of stacked memory modules are provided.

As an eighth embodiment of the present invention there is proposed a device comprising: a temperature estimation unit that calculates an estimated temperature of each of a plurality of stacked memory modules when a process of selecting one or more memory modules to which data is to be written simultaneously from among the plurality of stacked memory modules and a process of writing data to the selected one or more memory modules are executed repeatedly; and a selection data generation unit that selects memory modules in which a representative temperature of the estimated temperature of each of the plurality of stacked memory modules is lower than when memory modules are randomly selected in a process of selecting one or more memory modules to which data is to be written simultaneously based on the estimated temperature calculated by the temperature estimation unit, and generates selection data, which is a plurality of items of data identifying the selected one or more memory modules arranged chronologically in order of selection.

As a ninth embodiment of the present invention there is proposed a configuration in which, in the eighth embodiment, an identification data acquisition unit that acquires identification data that identifies eligible memory modules from among the plurality of stacked memory modules is provided, and the selection data generation unit generates selection data that identifies memory modules selected from among the eligible memory modules identified by the identification data.

As a tenth embodiment of the present invention there is proposed a program for causing a computer to function as: an identification data acquisition unit that acquires identification data identifying eligible memory modules from among a plurality of stacked memory modules; a temperature estimation unit that calculates an estimated temperature of each of the eligible memory modules identified by the identification data when a process of selecting one or more memory modules to which data is to be written simultaneously from among the eligible memory modules and a process of writing data to the selected one or more memory modules are executed repeatedly; and a selection data generation unit that selects memory modules in which a representative temperature of the estimated temperature of each of the eligible memory modules is lower than when memory modules are randomly selected in a process of selecting one or more memory modules to which data is to be written simultaneously based on the estimated temperature calculated by the temperature estimation unit, and generates selection data, which is a plurality of items of data identifying the selected one or more memory modules arranged chronologically in order of selection.

According to the present invention, the probability of data being written to two adjacent memory modules simultaneously or at close timings is reduced, making localized high temperature in a memory unlikely.

### BRIEF DESCRIPTION OF THE DRAWINGS

FIG. 1 is an external view of a data storage system as in one embodiment.

FIG. 2 is a drawing illustrating a physical configuration of the storage device as in one embodiment.

FIG. 3 is a drawing illustrating an arrangement of components such as memory modules provided by the storage device as in one embodiment.

FIG. 4 is a drawing illustrating a cross-sectional view of the storage device as in one embodiment.

FIG. 5 is a drawing illustrating a connection state between the components provided by the storage device as in one embodiment.

FIG. 6 is a drawing illustrating a functional configuration of the data-processing device as in one embodiment.

FIG. 7 is a drawing exemplifying a configuration of selection data used by the storage device as in one embodiment.

FIG. 8 is a drawing illustrating a functional configuration of the selection data generation device as in one embodiment.

FIG. 9 is a drawing exemplifying an arrangement of the memory modules selected as the data-writing destination in the storage device as in one embodiment.

FIG. 10 is a drawing exemplifying a configuration of selection data used by the storage device as in a modified example.

FIG. 11 is a drawing illustrating a functional configuration of the data-processing device as in a modified example.

FIG. 12 is a drawing illustrating an arrangement of components such as memory modules provided by the storage device as in a modified example.

FIG. 13 is a drawing illustrating a cross section of the storage device as in a modified example.

### DETAILED DESCRIPTION

### First Embodiment

A data storage system 1 as in the first embodiment of the present invention will now be explained. FIG. 1 is an external view of data storage system 1. Data storage system 1 comprises a data-processing device 11 that serves as a host, such as a CPU provided by a computer, for example, and a storage device 12 that reads/writes data in accordance with a request(s) from data-processing device 11.

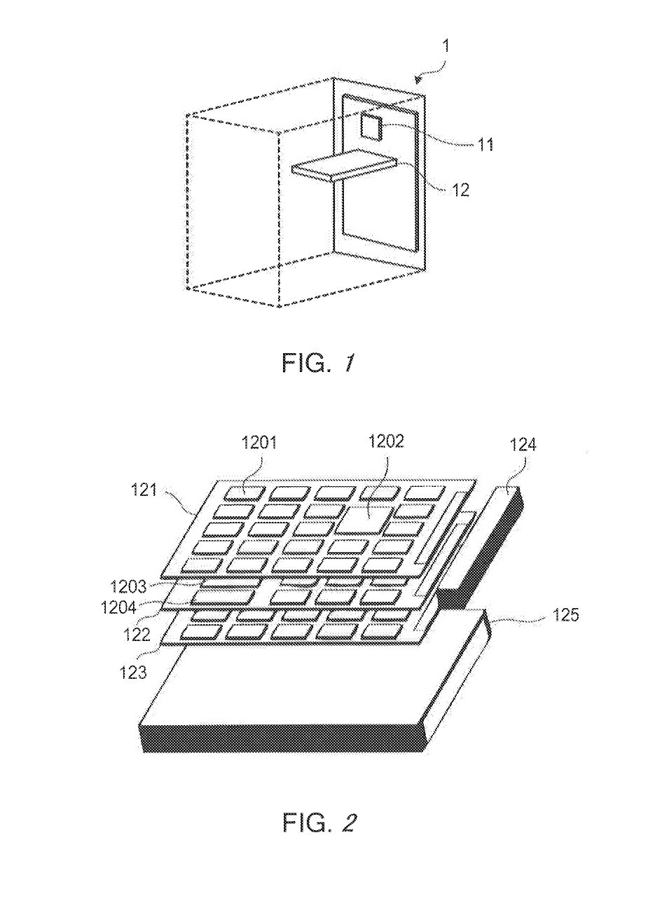

FIG. 2 is a drawing illustrating a physical configuration of a storage device 12. Storage device 12 comprises three memory boards 121, 122, and 123, an interface 124 for sending/receiving data between the three memory boards and data-processing device 11, and a housing 125 that accommodates the three memory boards and interface 124. Power required for operation of storage device 12 is supplied from a power source device (not illustrated) via interface 124. The number of memory boards provided by storage device 12 is not limited to three, and may be any number as long as storage device 12 comprises a plurality of stacked memory modules 1201.

Each of memory boards 121, 122, and 123 comprises a plurality of memory modules 1201 and two data-processing devices 1202 for reading/writing data from/to memory modules 1201 that constitute each of the memory boards, and performs controls such as specifying defective memory modules 1201. Memory module 1201 is a flash memory module, for example. However, memory module 1201 may be any type of memory module as long as it is a memory module whose temperature increases during reading/writing of data. Data-processing devices 1202 comprise CPLDs, for example. However, data-processing device 1202 may be any data-processing device system as long as it performs control of memory modules 1201 provided on one memory board.

Each of the two data-processing devices 1202 provided by each of memory boards 121, 122, and 123 controls memory modules 1201 that are provided on one surface of the memory board and memory modules 1201 that are provided on its other surface. The number of data-processing devices 1202 provided on one memory board is not limited to two, and one data-processing device 1202 may control all of memory modules 1201 provided on one of the surfaces of a memory board.

Memory board 122 comprises a data-processing device 1203 that controls reading/writing of data from/to the plurality of memory modules 1201 provided by memory boards 121, 122, and 123, and a memory 1204 that stores data used by data-processing device 1203. Data-processing device 1203 instructs reading/writing of data from/to any of data-processing devices 1202 of memory board 121, 122, or 123 in response to a request from data-processing device 11. Any of data-processing devices 1202 may perform reading/writing of data according to the instruction from data-processing device 1203. Data-processing device 1203 comprises an FPGA, for example. However, data-processing device 1203 may be any data-processing device system as long as it instructs reading/writing of data from/to the plurality of memory modules 1021 provided on a plurality of memory boards.

Memory 1204 is an EPROM. However, memory 1204 may be any type of memory as long as it stores data used by data-processing device 1203.

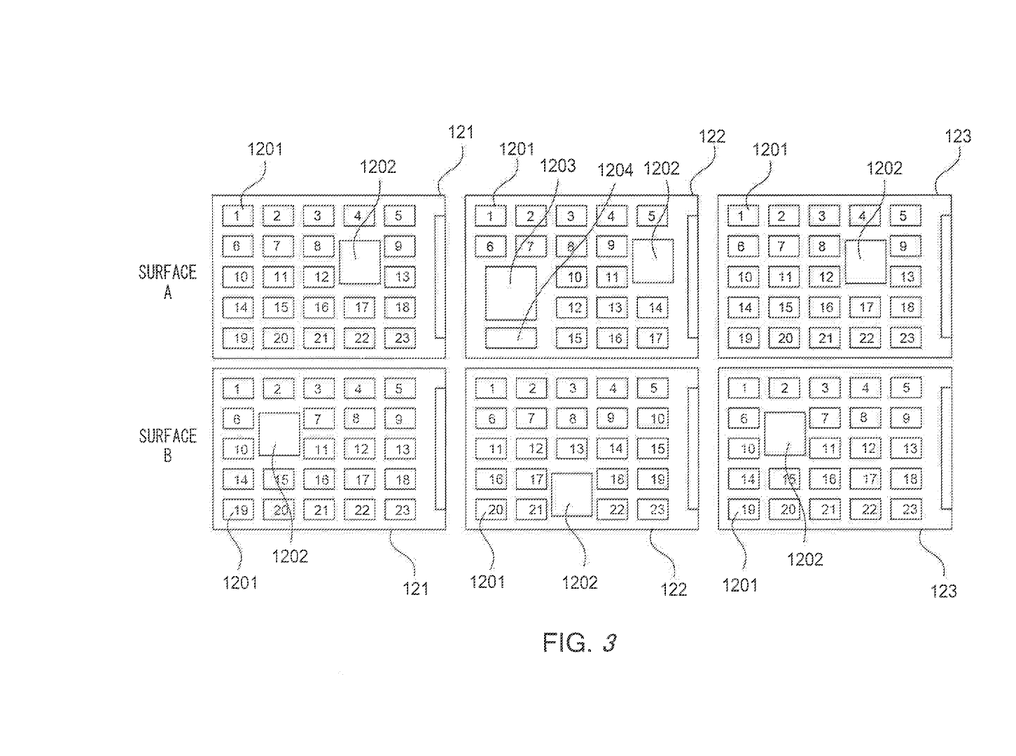

FIG. 3 is a drawing illustrating an arrangement of data-processing devices 1201 and 1202 provided by each of memory boards 121, 122, and 123, and data-processing device 1203 provided by memory board 122. Hereafter, with regard to memory boards 121, 122, and 123, the surface shown on the top side in FIG. 2 is referred to as surface A, and the surface shown on the bottom side is referred to as surface B. Of the six drawings illustrated in FIG. 3, the top three show surface A of memory board 121, surface A of memory board 122 and surface A of memory board 123, respectively, from left to right; and the bottom three show surface B of memory board 121, surface B of memory board 122 and surface C of memory board 123, respectively, from left to right. The number of memory modules 1201 illustrated in FIG. 3 is shown merely as an example, and a different number may be adopted. Further, the arrangement of memory modules 1201, data-processing devices 1202, and data-processing device 1203 illustrated in FIG. 3 is shown merely as an example, and a different arrangement may be adopted. In FIG. 3, the number assigned to each of memory modules 1201 is a number for identifying each of the plurality of memory modules 1201 on surface A or surface B of each of the memory boards.

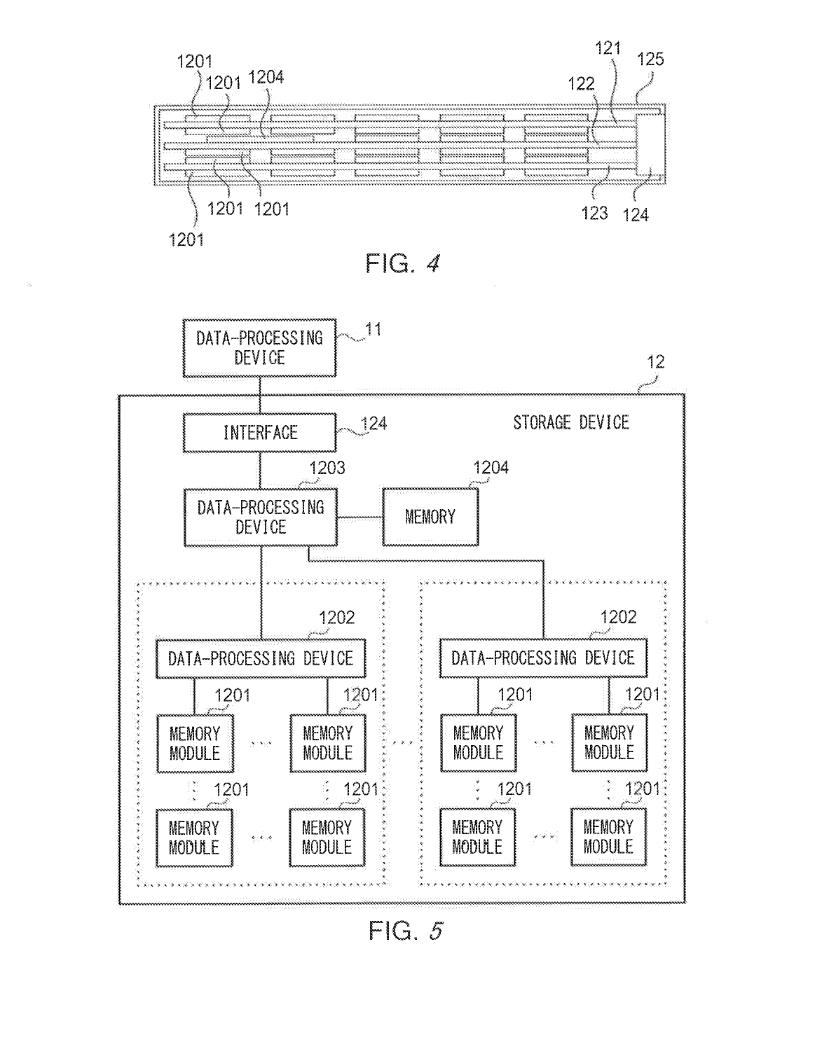

FIG. 4 is a drawing illustrating a cross-sectional view of storage device 12 in a state in which memory boards 121, 122, and 123 and interface 124 are accommodated in housing 125. A gap of 0.5 mm, for example, is provided between memory module 1201 on surface B of memory board 121 and memory module 1201 on surface A of memory board 122. Similarly, a gap of 0.5 mm, for example, is provided between memory module 1201 on surface B of memory board 122 and memory module 1201 on surface A of memory board 123. However, the size of the gaps is not restricted to 0.5 mm. Further, a heat-conducting cushion material that serves as an accelerator for conducting heat to housing 125 and a buffer may be provided.

A heat-conducting cushion material (not illustrated) that serves to accelerate heat conduction to housing 125 and a buffer are provided between memory modules 1201 on surface A of memory board 121 and housing 125, and between memory modules 1201 on surface B of memory board 123 and housing 125.

FIG. 5 is a drawing illustrating a state of the connection between the components provided by storage device 12. Interface 124 is connected to data-processing device 11. Interface 124 receives data read/write requests from data-processing device 11, and on receiving a data read request, receives the requested data from data-processing device 1203 and delivers the data to data-processing device 11.

Data-processing device 1203 is connected to each of interface 124, memory 1204, and data-processing devices 1202. When a data write request is received from data-processing device 11 via interface 124, data-processing device 1203 selects memory modules 1201 as writing destinations of the data corresponding to the request, and instructs data-processing devices 1202 that control the selected writing destination memory modules 1201 to write the data. Further, when a data read request is received from data-processing device 11 via interface 124, data-processing device 1203 specifies memory modules 1202 to which data is to be written in accordance with the request, and instructs data-processing devices that control the specified memory modules 1201 to read the data. Data-processing device 1203 outputs the data delivered from data-processing devices 1202 to data-processing device 11 via interface 124 in accordance with the instruction.

Memory 1204 stores various types of data used by data-processing device 1203. The various types of data used by data-processing device 1203 include selection data (described below) that indicates rules for selecting memory modules 1201 as data writing destinations, identification data (described below) that identifies eligible memory modules from among memory modules 1201, and the like.

Storage device 12 comprises a total of six data-processing devices arranged on surfaces A and B of each of memory boards 121, 122, and 123. Each of the six data-processing devices 1202 is connected to the memory modules 1201 arranged on one surface of a memory board, and controls the memory modules 1201. Hereafter, data-processing devices 1202 and the memory modules 1201 controlled by the data-processing devices are collectively referred to as a “memory unit.” Accordingly, storage device 12 comprises six memory units. However, the number of memory units provided by storage device 12 is not restricted to six.

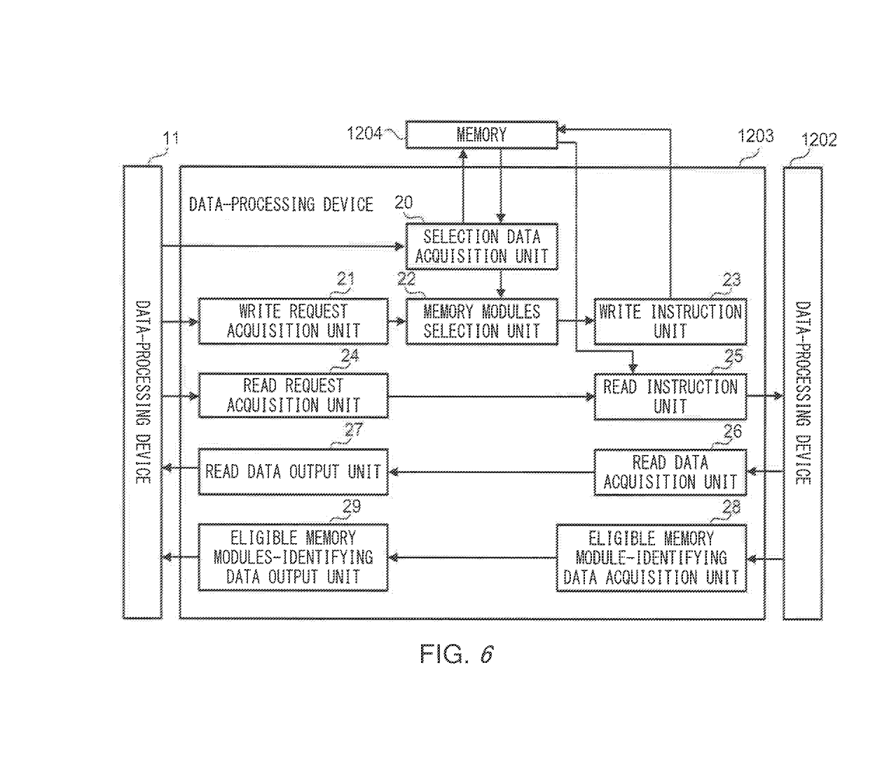

FIG. 6 is a drawing illustrating a functional configuration of data-processing device 1203. Firstly, data-processing device 1203 comprises a selection data acquisition unit 20 that reads and acquires selection data stored in memory 1204.

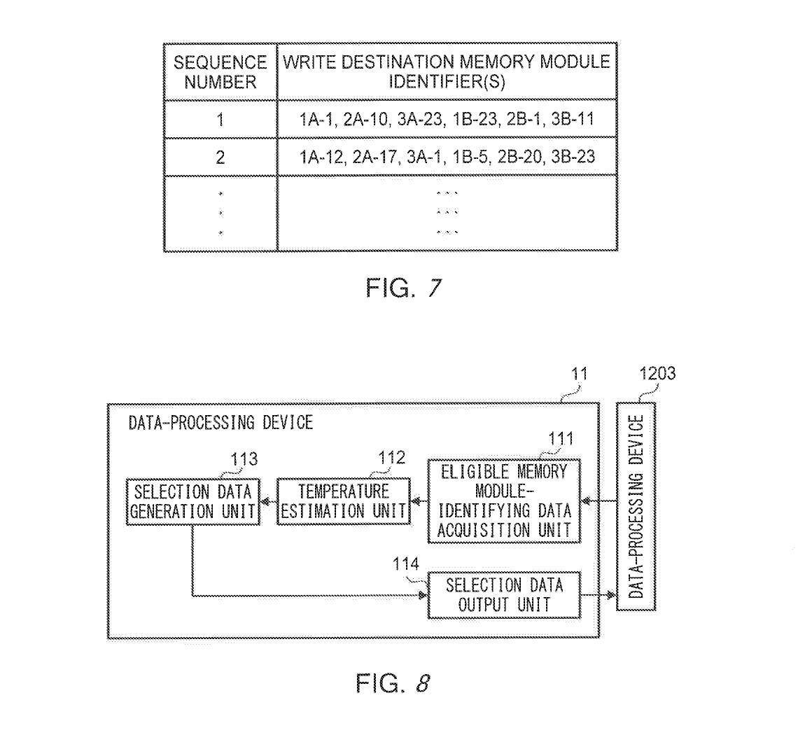

FIG. 7 is a drawing illustrating an example of a configuration of selection data used by storage device 12. Selection data is a list that contains a sequence number field and a write destination memory module identifier field, and indicates that data should be written to memory modules 1201 identified by each of the write destination memory module identifiers stored in the write destination memory module identifier field in an order corresponding to the sequence numbers stored in the sequence number field.

In the example shown in FIG. 7, a “1A-2” format is adopted as the format of the write destination memory module identifiers. The first character of a write destination memory module identifier indicates the last number of the number of memory board 121, 122, or 123, and indicates the memory board on which the memory modules 1201 are arranged. The second character of a write destination memory module identifier indicates whether the memory modules 1201 are arranged on surface A or surface B of a memory board. The number that follows the “-” of a write destination memory module identifier indicates an identifier (a number assigned to a memory module 1201 in FIG. 3) of memory module 1201 in a memory unit. However, the format of selection data is not limited to the format exemplified in FIG. 7, and any format can be adopted as long as memory module 1201 can be identified.

When a plurality of write destination memory module identifiers are stored in the write destination memory module identifier field, the selection data indicates that data should be written simultaneously to the plurality of memory modules 1201 identified by the write destination memory module identifiers.

Returning to FIG. 6, the functional configuration of data-processing device 1203 will be explained in more detail. Data-processing device 1203 further comprises a write-request acquisition unit 21 (an example of a request acquisition unit) that acquires data write requests from data-processing device 11, a memory module selection unit 22 (an example of a selection unit) that selects the data write destination corresponding to the write request acquired by write request acquisition unit 21 from among the plurality of memory modules 1201 in accordance with the selection data acquired by selection data acquisition unit 20, and write instruction unit 23 that instructs data-processing device 1202 that controls the memory modules 1201 selected by memory module selection unit 22 to write the data. Data-processing device 1202 writes data to the selected memory modules 1201 in accordance with instructions from write instruction unit 23. Further, write instruction unit 23 stores, in memory 1204, mapping data in which, for each item of data for which writing has been instructed, the data identifier and the identifier of the memory modules 1201 selected as data write destinations are associated.

Further, data-processing device 1203 comprises: a read request acquisition unit 24 that acquires data read requests from data-processing device 11; a read instruction unit 25 that instructs data-processing device 1202, which controls memory modules 1201, to which data corresponding to the read requests acquired by read request acquisition unit 24 according to mapping data stored in memory 1204 is written, to read data; a read data acquisition unit 26 that acquires from data-processing devices 1202 data read from memory modules 1201 in accordance with the instruction from read instruction unit 25; and a read data output unit 27 that outputs the data acquired by read data acquisition unit 26 to data-processing device 11 as a response to the read requests acquired by read request acquisition unit 24.

Further, data-processing device 1203 comprises: an eligible memory module identification data acquisition unit 28 (an example of an identification data acquisition unit) that acquires, from each of data-processing devices 1202, eligible memory module identification data that identifies eligible memory modules 1201 from among the memory modules 1201 controlled by data-processing devices 1202; and eligible memory module identification data output unit 29 (an example of an identification data output unit) that outputs, to data-processing device 11, eligible memory module identification data acquired by eligible memory module identification data acquisition unit 28. The format of the eligible memory module identification data is not limited as long as the data identifies which of the plurality of memory modules 1201 provided in storage devices 12 are eligible. That is, the eligible memory module identification data is not limited to data that directly identifies the eligible memory modules 1201, and may be data that can identify eligible memory modules 1201 by identifying the memory modules 1201 that are not eligible, for example.

Data-processing device 11 outputs updated selection data to storage device 12 as a response to the eligible memory module identification data output from eligible memory module identification data output unit 29. The selection data output from data-processing device 11 is acquired by selection data acquisition unit 20, and stored in memory 1204. Subsequently, selection data acquisition unit 20 reads and acquires the updated selection data from memory 1204.

Data-processing device 11 functions as a device for generating selection data (hereafter referred to as “selection data generation device”) by performing processes according to a program stored in a data storage device (not illustrated in FIG. 1) such as an SSD.

FIG. 8 is a drawing illustrating the functional configuration of data-processing device 11 that functions as a selection data generation device. Data-processing device 11 comprises: an eligible memory module identifying data acquisition unit 111 that acquires eligible memory module identification data that is output from eligible memory module identification data output unit 29 of data-processing device 1203; a temperature estimation unit 112 that calculates an estimated temperature (convergence value, for example) of each of memory modules 1201 when data is continuously written in order to memory modules 1201 identified by the eligible memory module identification data acquired by eligible memory module identification data acquisition unit 111; a selection data generation unit 113 that generates selection data indicating the sequence of the memory modules 1201 to be write destinations, in which the representative value of temperature (maximum value, for example) of memory modules 1201 estimated based on the estimated temperature of each of the memory modules 1201 calculated by temperature estimation unit 112 is low; and a selection data output unit 114 that outputs selection data generated by selection data generation unit 113 to data-processing device 1203.

Temperature estimation unit 112, for example, acquires parameters for each housing 125 that comprises storage device 12, substrate of each memory board, memory modules 1201 arranged on each memory board, data-processing devices 1202, data-processing device 1203, memory 1204, interface 124, the heat-conducting cushion material, the air inside housing 125, the air outside housing 125, and the like. These parameters include heat conduction rate, heat capacity, contact surface area between other components that come into contact, thickness in the direction of heat conduction, and amount of heat generated by memory modules 1201, data-processing devices 1202, data-processing device 1203 and the like as a result of writing of one unit amount of data. Temperature estimation unit 112 then estimates the heat distribution in storage device 12 when data is written repeatedly according to various write sequences (in which memory modules 1202 to be write destinations are selected from among eligible memory modules 1201 and arranged chronologically) by means of a simulation or the like using a known heat conduction equation.

Selection data generation unit 113 generates, as selection data that is desirable from the viewpoint of reduction of temperature rise, selection data indicating the write sequence in which the maximum estimated temperature of each of memory modules 1201 is the lowest, for example, based on the heat distribution of storage device 12 estimated by temperature estimation unit 112 for each of a variety of write sequences. Selection data generation unit 113 randomly selects at least the memory modules 1201 to be write destinations from among the eligible memory modules 1201, compares the selected memory modules 1201 with writing sequences that have been arranged chronologically, and indicates a write sequence in which the representative value (maximum value, for example) of the estimated temperature of memory modules 1201 is low.

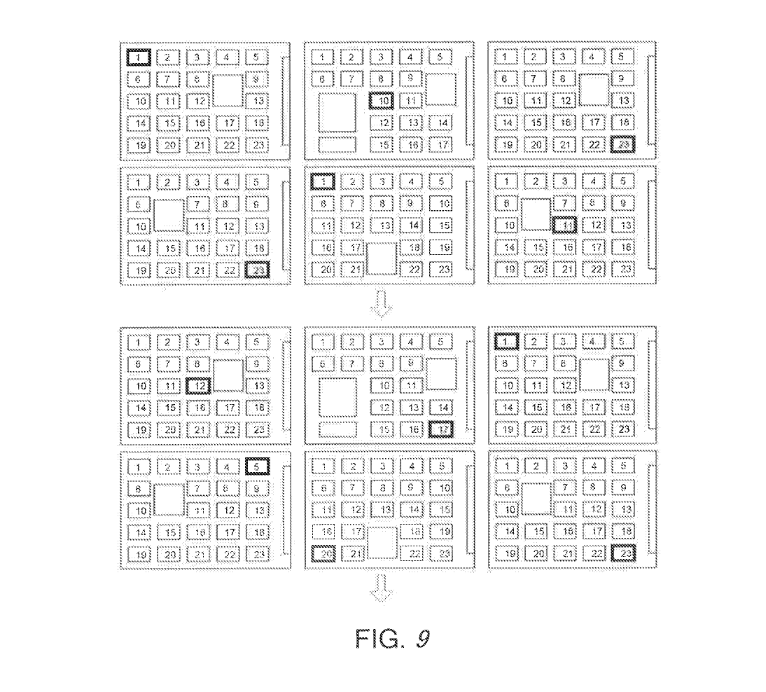

FIG. 9 is a drawing exemplifying memory modules 1201 that are to be the write destinations of data according to selection data generated by data-processing device 11 as described above. The top two rows in FIG. 9 illustrate memory modules 1201 that are identified by write destination memory module identifiers corresponding to sequence number “1” of the selection data (FIG. 7). That is, the memory modules 1201 illustrated in the top two rows in FIG. 9 indicate memory modules 1201 to which data (each of a plurality of data blocks divided into write request targets) should be written at a first write timing corresponding to sequence number “1.”

Further, the two bottom rows in FIG. 9 indicate memory modules 1201 that are identified by write destination memory module identifiers corresponding to sequence number “2” of the selection data. That is, the memory modules 1201 illustrated in the bottom two rows in FIG. 9 indicate memory modules 1201 to which data should be written at a second write timing (a write timing subsequent to the first write timing) corresponding to sequence number “2.”

As illustrated in FIG. 9, memory modules 1201 to be write destinations selected according to the selection data are often selected in such a manner that memory modules 1201 to which data is written simultaneously are not adjacent to one another. Further, memory modules 1201 that are to be write destinations selected according to the selection data are often selected in such a manner that memory modules 1201 to which data is written at subsequent write timings are not adjacent to memory modules 1201 to which data is written at preceding write timings. This is because the selection data indicates a write sequence that reduces localized heating in storage device 12.

As described above, according to data storage system 1, as a result of data being written, in order, to memory modules 1201 that are suitably selected from among the plurality of stacked memory modules 1201 provided by storage device 12, heating of memory modules 1201 is reduced. With regard to reading of data, since a series of data is read in the order of writing, according to data storage system 1, heating of memory modules 1201 due to heat generated by reading of data is also reduced.

Further, according to data storage system 1, if any of memory modules 1201 malfunctions and becomes unusable, selection data in which memory modules 1201 that are to be write destinations are selected from among eligible memory modules 1201 is generated, and used for subsequent processing. Accordingly, even if one or more memory modules 1201 become unusable due to deterioration of storage device 12 over time or the like, it is unlikely that heating of memory modules 1201 will occur.

### MODIFIED EXAMPLES

The embodiment described above can be modified in various ways within the technical scope of the present invention. Examples of such modifications are described below. Two or more of the embodiments described above and modified examples described below may be combined, as appropriate.

(1) A configuration may be adopted in which storage device 12 is provided with a temperature sensor that measures temperatures at representative points of the plurality of memory modules 1201, and selection data indicating a different write sequence is selectively used in accordance with the temperatures measured by the temperature sensor.

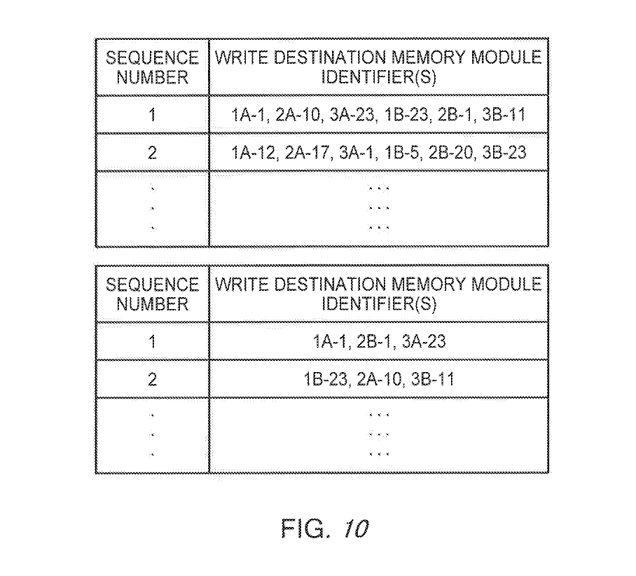

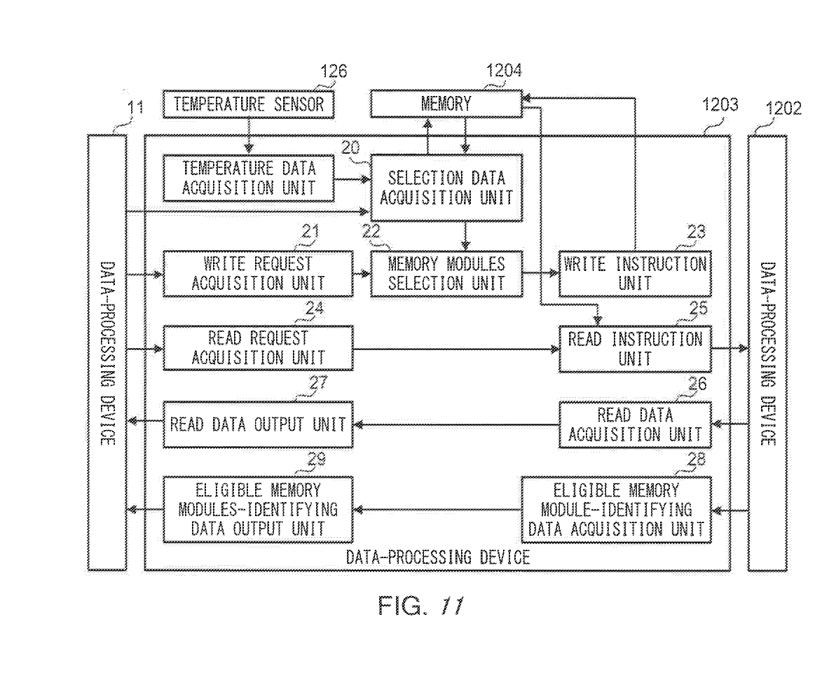

In this modified example (hereafter referred to as “first modified example”), a plurality of items of selection data such as those illustrated in FIG. 10 are stored in memory 1204. When following the selection data shown at the top of FIG. 10 (hereafter referred to as “first selection data”), the number of memory modules 1201 to which data is written simultaneously is six, and when following the selection data at the bottom of FIG. 10 (hereafter referred to as “second selection data”), the number of memory modules 1201 to which data is written simultaneously is three.

Accordingly, heating of memory modules 1201 can be reduced by configuring memory module selection unit 22 so that, while the temperature measured by the temperature sensor is equal to or lower than a threshold value, the first selection data is used, and when the temperature measured by the temperature sensor exceeds the threshold value, the second selection data is used, for example.

FIG. 11 is a drawing illustrating the functional configuration of data-processing device 1203 as in the first modified example. Data-processing device 1203 as in the first modified example comprises a temperature data acquisition unit 30 that acquires temperature data indicating the temperatures (temperatures at representative points of memory modules 1201) measured by temperature sensor 126. In the first modified example, selection data acquisition unit 20 reads the first selection data from memory 1204 while the temperature indicated by temperature data acquired by temperature data acquisition unit 30 is equal to or lower than a predetermined threshold value, and reads the second selection data from memory 1204 if the temperature indicated by the temperature data exceeds the predetermined threshold value. Memory module selection unit 22 selects, in order, memory modules 1202 to be write destinations according to the selection data read by selection data acquisition unit 20. As a result, the number of memory modules 1202 that are write destinations to which data is written within a predetermined time changes according to the temperature indicated by the temperature data.

In the first modified example, the number of items of selection data used selectively is not limited to two, and three or more items of selection data (data in which the number of memory modules 1201 that are write destinations to which data is written simultaneously differs) may be used.

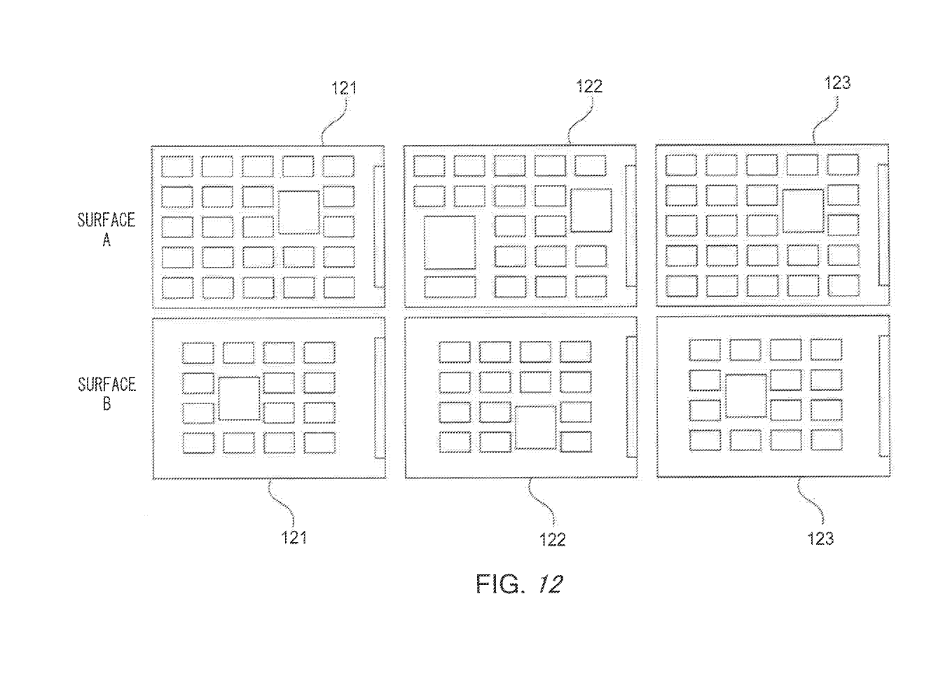

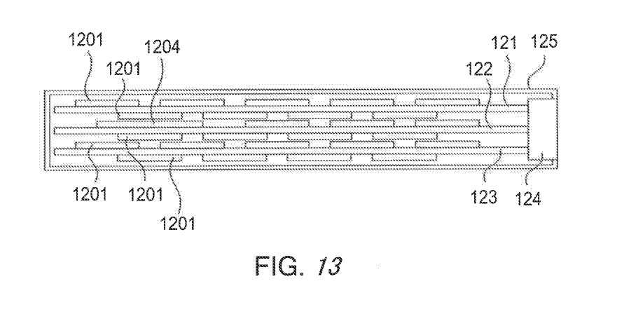

(2) The components of memory modules 1201 and the like in storage device 12 may be arranged so that heating of memory modules 1202 is reduced by simulated or actual heat distribution or the like. For example, FIG. 12 exemplifies memory boards in which an arrangement that is different from the arrangement of memory modules 1201 and the like illustrated in FIG. 3 is adopted. If the arrangement illustrated in FIG. 12 is adopted, as illustrated in FIG. 13, stacked memory modules 1201 face one another in positions offset in the direction along the substrate. As a result, the heat generated when data is read/written from/to a certain memory module 1201 is transmitted to a greater number of adjacent memory modules 1201 compared to when the arrangement illustrated in FIG. 3 is adopted, but the amount of heat received by each of memory modules 1201 is less than the amount of heat received when the arrangement of FIG. 3 is adopted. As a result, the arrangement illustrated in FIG. 3 and the arrangement illustrated in FIG. 12 can result in different heat distributions in storage device 12. If data is repeatedly written according to certain selection data, it is desirable to select an arrangement in which heating is further reduced.

(3) In the embodiment described above, the selection data is generated based on the heat distribution in memory modules 1201 estimated by performing a simulation. In place thereof, selection data generated based on actually measured heat distribution may be used.

(4) In the embodiment described above, the selection data is generated by data-processing device 11, which is the source of a request of data reading/writing. In place thereof, a configuration may be adopted in which storage device 12 comprises a data-processing device such as a CPU, and said data-processing device generates selection data.

(5) Data-processing device 1203 may incorporate the function of data-processing device 1202. Further, data-processing device 11 may incorporate the function of data-processing device 1203.

(6) In the embodiment described above, memory module selection unit 22 of data-processing device 1203 selects memory modules 1202 to be write destinations according to selection data. A method in which data-processing device 1203 selects memory modules 1201 to be write destinations according to selection data is not limited thereto. For example, if data-processing device 1203 comprises a logic integration circuit, memory module selection unit 22 may be realized by establishing, using logic cells and the like provided by data-processing device 1203, a logic circuit that calculates a sequence of write destination memory modules 1201 according to a predetermined algorithm.

Accordingly, if, for example, data-processing device 1203 is an FPGA, a configuration may be adopted in which selection data is read in a block RAM within the FPGA from memory 1204 during startup of the FPGA, and memory module selection unit 22 that is realized by a logic cell group during configuration of the FPGA (setting of logical operation of the logic cells according to a program stored in memory 1204 and connection between logic cells by connecting internal wires) selects memory modules 1201 with reference to the selection data stored in the block RAM (one example of the embodiment described above), or a configuration may be adopted in which, without using selection data, memory module selection unit 22 that selects memory modules 1201 to be write destinations according to a predetermined algorithm during configuration of the FPGA is established by a logic cell group (one example of the present modified example).

(7) The number, arrangement, data and the like of the components of data storage system 1 indicated in the embodiment described above and the modified examples are merely examples, and the present invention is not limited thereto.

### EXPLANATION OF THE REFERENCE NUMERALS

1 . . . data storage system, 11 . . . data-processing device(s), 12 . . . storage device, 20 . . . selection data acquisition unit, 21 . . . write request acquisition unit, 22 . . . memory modules selection unit, 23 . . . write instruction unit, 24 . . . read request acquisition unit, 25 . . . read instruction unit, 26 . . . read data acquisition unit, 27 . . . read data output unit, 28 . . . eligible memory module-identifying data acquisition unit, 29 . . . eligible memory modules-identifying data output unit, 30 . . . temperature data acquisition unit, 111 . . . eligible memory module-identifying data acquisition unit, 112 . . . temperature estimation unit, 113 . . . selection data generation unit, 114 . . . selection data output unit, 121 . . . memory board, 122 . . . memory board, 123 . . . memory board, 124 . . . interface, 125 . . . Housing, 126 . . . temperature sensor, 1201 . . . memory module, 1202 . . . data-processing device 1203 . . . data-processing device(s), 1204 . . . memory

What is claimed is:

1-10. (canceled)

11. A device comprising:
a request acquisition unit that acquires a data write request;
a selection unit that selects write destination memory modules from among a plurality of stacked memory modules in accordance with the data write request, so that two or more memory modules to which data is written within a predetermined time frame are not adjacent to one another; and
a write instruction unit that instructs writing of data to the memory modules selected by the selection unit in accordance with the data write request.

12. A device as set forth in claim 11, wherein:
the selection unit selects the write destination memory modules from among the plurality of stacked memory modules so that two or more memory modules to which data is written simultaneously are not adjacent to one another.

13. A device as set forth in claim 11, wherein:
if the selection unit selects, from among the plurality of stacked memory modules, a first memory module to which data is to be written at a first write timing, the selection unit selects a memory module that is not adjacent to the first memory module as a second memory module to which data is to be written at a second write timing, the second write timing being subsequent to the first write timing.

14. A device as set forth in claim 11, wherein:
a selection data acquisition unit that acquires selection data, which is a plurality of items of data that identify one or more memory modules selected from among the plurality of stacked memory modules, arranged chronologically, is provided, and
the selection unit selects memory modules as write destinations according to the selection data.

15. A device as set forth in claim 14, wherein:
an identification data acquisition unit that acquires identification data that identifies eligible memory modules from among the plurality of stacked memory modules and an identification data output unit that outputs the identification data are provided, and
the selection data acquisition unit acquires the selection data that is input as a response to the output of the identification data.

16. A device as set forth in claim 11, wherein:
a temperature data acquisition unit that acquires temperature data indicating a temperature measured at a representative point of the plurality of stacked memory modules is provided, and the selection unit modifies a number of two or more memory modules to which data is to be written within a predetermined time in accordance with the temperature indicated by the temperature data.

17. A device as set forth in claim 11, wherein:
the plurality of stacked memory modules are provided.

18. A device comprising:
a temperature estimation unit that calculates an estimated temperature of each of a plurality of stacked memory modules when a process of selecting one or more memory modules to which data is to be written simultaneously from among the plurality of stacked memory modules and a process of writing data to the selected one or more memory modules are executed repeatedly; and
a selection data generation unit that selects memory modules in which a representative temperature of the estimated temperature of each of the plurality of stacked memory modules is lower than when memory modules are randomly selected in a process of selecting one or more memory modules to which data is to be written simultaneously based on the estimated temperature calculated by the temperature estimation unit, and generates selection data, which is a plurality of items of data identifying the selected one or more memory modules arranged chronologically in order of selection.

19. A device as set forth in claim 18, wherein:
an identification data acquisition unit that acquires identification data that identifies eligible memory modules from among the plurality of stacked memory modules is provided, and
the selection data generation unit generates selection data that identifies memory modules selected from among the eligible memory modules identified by the identification data.

20. A program stored on a non-transitory computer readable medium, the program for causing a computer to function as:
an identification data acquisition unit that acquires identification data identifying eligible memory modules from among a plurality of stacked memory modules;
a temperature estimation unit that calculates an estimated temperature of each of the eligible memory modules identified by the identification data when a process of selecting one or more memory modules to which data is to be written simultaneously from among the eligible memory modules and a process of writing data to the selected one or more memory modules are executed repeatedly; and
a selection data generation unit that selects memory modules in which a representative temperature of the estimated temperature of each of the eligible memory modules is lower than when memory modules are randomly selected in a process of selecting one or more memory modules to which data is to be written simultaneously based on the estimated temperature calculated by the temperature estimation unit, and generates selection data, which is a plurality of items of data identifying the selected one or more memory modules arranged chronologically in order of selection.
